(19) United States
(12) Patent Application Publication
(10) Pub. No.: US 2015/0277025 A1
(43) Pub. Date: Oct. 1, 2015

(54) FINE LINE GRIDABLE LIGHT PANEL

(71) Applicant: ACRYLIC DESIGN ASSOCIATES, INC., Plymouth, MN (US)

(72) Inventors: William J. McNeely, Chanhassen, MN (US); Daniel W. Hills, Blaine, MN (US)

(73) Assignee: ACRYLIC DESIGN ASSOCIATES, INC.

(21) Appl. No.: 14/668,221

(22) Filed: Mar. 25, 2015

Related U.S. Application Data
(60) Provisional application No. 61/971,167, filed on Mar. 27, 2014.

(51) Int. Cl. F21V 8/00; H05K 5/02; H05K 5/00

(52) U.S. Cl. CPC G02B 6/0051; G02B 6/0073; G02B 6/0078; G02B 6/0088; G02B 6/005; G02B 6/0065; H05K 5/0017; H05K 5/0204

(57) ABSTRACT

A gridable light panel with a reduced edge profile that permits a high percentage of the image to be visible within the viewable image area. When viewed from a distance, the frame edge is substantially invisible so that adjacent images appear to be a single image. The frame structure includes front supports along an inner surface that capture edges of a light diffuser panel. Inner edges of the front supports surround a viewable image area. Rear supports are located along the rear surface of the light diffuser panel. The rear supports extend into the viewable image area in an overlapping region. An image is secured to the front surface of the light diffuser panel.

### RELATED APPLICATIONS

The present application claims the benefit of U.S. Provisional Application No. 61/971,167, entitled Gridable Light Panel, filed Mar. 27, 2014, the entire disclosure of which is hereby incorporated by reference.

### FIELD OF THE INVENTION

The present disclosure is directed to a fine line gridable light panel with a reduced edge profile that permits a high percentage of the image to be visible within the viewable image area. When viewed from a distance, the frame edge is substantially invisible so that adjacent images appear to be a single image.

### BACKGROUND OF THE INVENTION

Light panels are widely used in commercial places, such as factories, offices, hospitals, schools, and stores for informational and advertising purposes. Two of the primary lighting panel structures are direct-lit backlight modules and edge-lit modules.

Direct-lit light panels provide more uniform light compared with the typical edge-lit light panel, especially for large-scale applications. The fluorescent tubes used in some direct-lit light panels, however, result in a thicker profile than an edge-lit light panel with a comparable lighted surface. Light-emitting diode or LED light sources have been incorporated into direct-lit light panels to reduce the profile, but require extra cost to convert the dot light sources generated by an LED array to a uniform surface light source.

Edge-lit light panels that use LED's as the light source permit a thin profile, but the edge structure that houses the LED's can create a shadow or uneven lighting along the perimeter of the light panel. This edge effect is compounded when multiple light panels are arranged in an array, creating a dark gap between adjacent images.

### BRIEF SUMMARY OF THE INVENTION

The present disclosure is directed to a gridable light panel having a thin-edge frame with a reduced edge profile. The frame structure includes front supports along an inner surface that capture edges of a light diffuser panel. Inner edges of the front supports surround a viewable image area. Rear supports are located along the rear surface of the light diffuser panel. The rear supports extend into the viewable image area in an overlapping region. An image is secured to the front surface of the light diffuser panel.

A protective layer or lens is optionally secured to the front surface of the image by the front supports. Transparent removal tabs can optionally be attached to the lens to facilitate removal for replacing the image. A transparent adhesive is used to attach the removal tab to a rear surface of the lens. The removal tabs are bent about 90 degrees and extend past the front support so as to be easily grasped. The unique design of the lens, combined with the transparent removal tab, allows 2-dimensional graphic images to be easily inserted and replaced without tools and without removing the frame from its display position.

The present fine line gridable light panel is designed to display both illuminated and non-illuminated graphics, as well as three-dimensional images. Illuminated and non-illuminated graphics preferably share the same frame allowing any combination of illuminated and non-illuminated images to be positioned adjacently with a minimal gap between images. The images may be printed or displayed on a variety of substrates including films, plastics, papers, magnetized materials, and fabric. Three-dimensional versions may be constructed of a variety of materials that include metals, plastics, wood and composites thereof.

The front supports on the present thin edge frame permit adjacent images to be positioned close together. The front supports preferably have a width of less than about 0.150 inches, and more preferably less than about 0.100 inches. As a result, adjacent images can be located less than about 0.300 inches apart, and more preferably less than about 0.200 inches apart. When viewed from a distance, the fine line of the frame edge is substantially invisible so that adjacent images appear to be a single image.

The front supports also permit the images to be substantially fully visible within the viewable image area, both vertically and horizontally. The front supports extend onto the front surface of the light diffuser panel less than about 0.100 inches, and preferably less than about 0.070 inches, and more preferably less than about 0.040 inches. As a result, the present thin edge frame permits at least 97%, and more preferably at least 98% of the image to be visible within the viewable image area (depending upon the overall size of the image). For example, a standard frame typically has a border of about one inch to hold a graphic in place that will obscure over 16% of a 22″×28″ image. The present fine line gridable light panel allows 99.35% visibility of the same 22″×28″ image. In the preferred embodiment, less than about 3%, and preferably less than about 2% of a 24″×24″ the image is obscured by the front supports.

The rear supports extend into the viewable image area in an overlapping region. By minimizing the length of the rear support required to optimally position the lens, diffuser and light panel within the frame, the resulting shadow is less visually impactful. This design results in a bright and even illumination over the entire image to within a few millimeters of the edge of the graphic. The overlapping region preferably has a width of less than about 0.300 inches, and more preferably about 0.250 inches.

In one embodiment, the rear supports are light transmitting insert secured to inner surface of the frame structure. In another embodiment, the light transmitting structures include one or more apertures are formed in the rear supports. The light transmitting structures formed in the rear supports transmit light to the viewable image area in the overlapping region with an intensity at least 25% greater than a light intensity exhibited in an overlapping region of a rear support without light transmitting structures.

The present fine line gridable light panel can be single-sided or double-sided, and can be mounted either vertically or horizontally. In a single sided application the frame depth is less than about 1.5 inches, and preferably less than about 1.25 inches. For a double-sided application the frame depth is less than about 2.0 inches, and preferably less than about 1.875″. In the horizontal configuration, the gridable light panels can operate as shelves. The light source can optionally illuminate the shelf (and any image located in the light panel) and project light from the underside of the shelf.

The gridable light panel can be supported by a backer panel. A power supply for the light source is preferably mounted to the backer panel. In another embodiment, the backer panel is configured to support a plurality of gridable light panels.

In some embodiments, mounting brackets for the gridable light panels also serve as connectors to a power source for the light source. The light panel is powered simply by inserting the mounting brackets into receptacles on an electrified support track. This “plug and play” approach allows the light panels to be quickly and easily removed and replaced.

### BRIEF DESCRIPTION OF THE SEVERAL VIEWS OF THE DRAWING

FIG. 1 is an exploded view of a gridable light panel in accordance with an embodiment of the present disclosure.

FIG. 2A is a front view of the light panel of FIG. 1.

FIG. 2B is a side view of the light panel of FIG. 1.

FIG. 2C is a rear view of the light panel of FIG. 1.

FIG. 3 is a sectional view of the light panel of FIG. 1.

FIGS. 4A-5B illustrate various light transmitting structures of alternative frame members in accordance with an embodiment of the present disclosure.

FIG. 6 is a perspective view of an alternative frame member in accordance with an embodiment of the present disclosure.

FIG. 7 is a perspective view of an alternative frame member in accordance with an embodiment of the present disclosure.

FIG. 8 is a perspective view of a light panel assembly in accordance with an embodiment of the present disclosure.

FIGS. 9A and 9B are perspective views of an array of light panels in accordance with an embodiment of the present disclosure.

FIG. 10 is a perspective view of an array of light panels of differing sizes in accordance with an embodiment of the present disclosure.

FIG. 11 is a sectional view of an interface of two light panels in accordance with an embodiment of the present disclosure.

FIG. 12 is a perspective view of two light panels in a back-to-back configuration in accordance with an embodiment of the present disclosure.

FIGS. 13A-13C is a two-sided light box with unitary frame members in accordance with an embodiment of the present disclosure.

FIGS. 14A and 14B illustrate an embodiment of the present light panel used as a shelf in accordance with an embodiment of the present disclosure.

FIG. 14C illustrates support brackets that mate with a corresponding support track to provide power to the light panel in accordance with an embodiment of the present disclosure.

FIGS. 15A and 15B illustrate transparent lens removal tabs in accordance with an embodiment of the present disclosure.

### DETAILED DESCRIPTION OF THE INVENTION

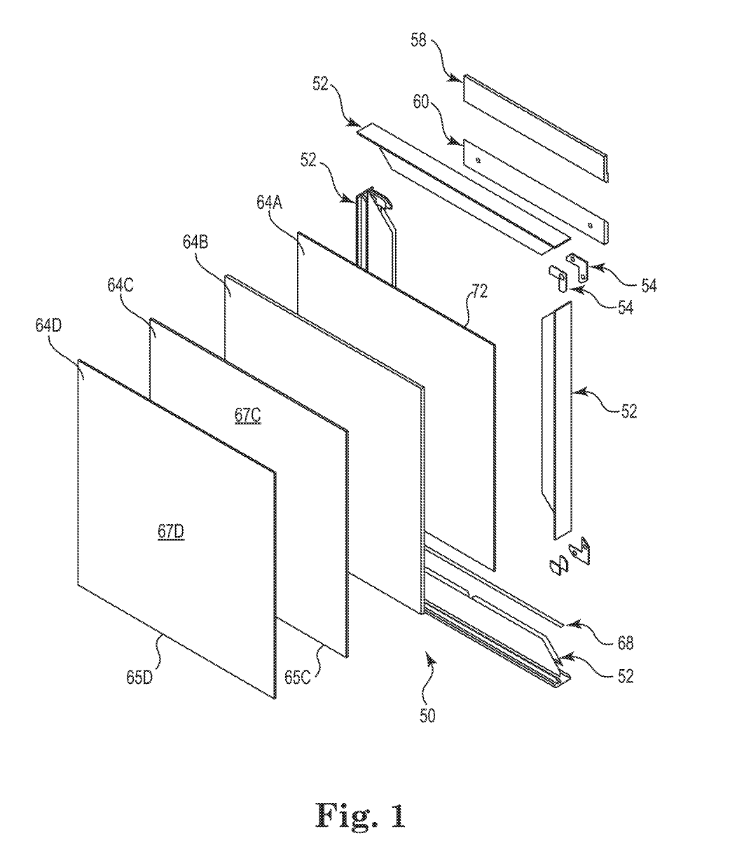

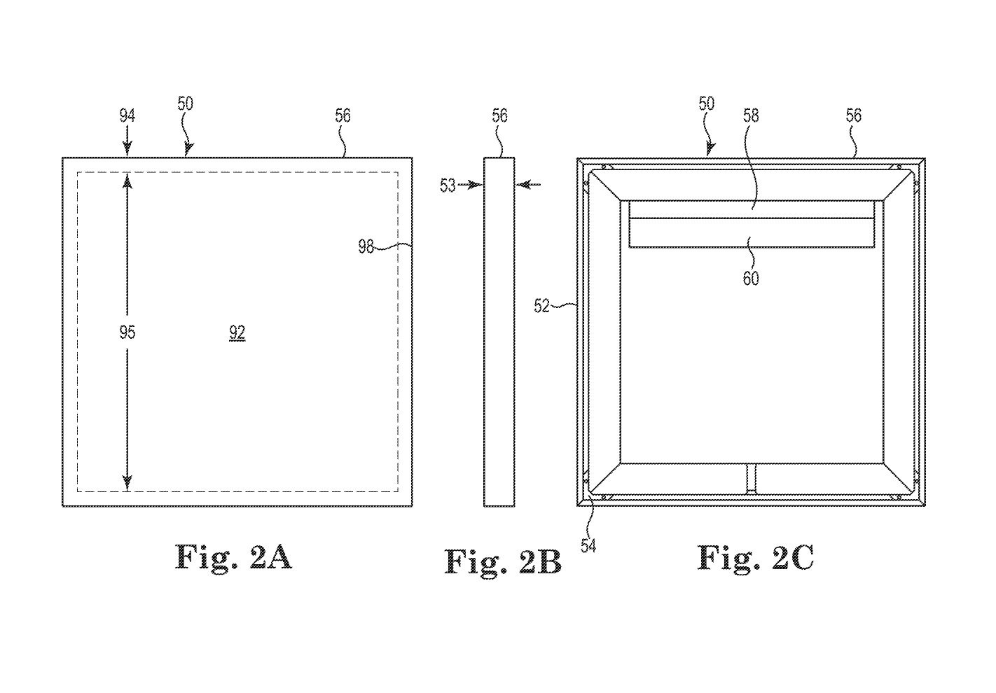

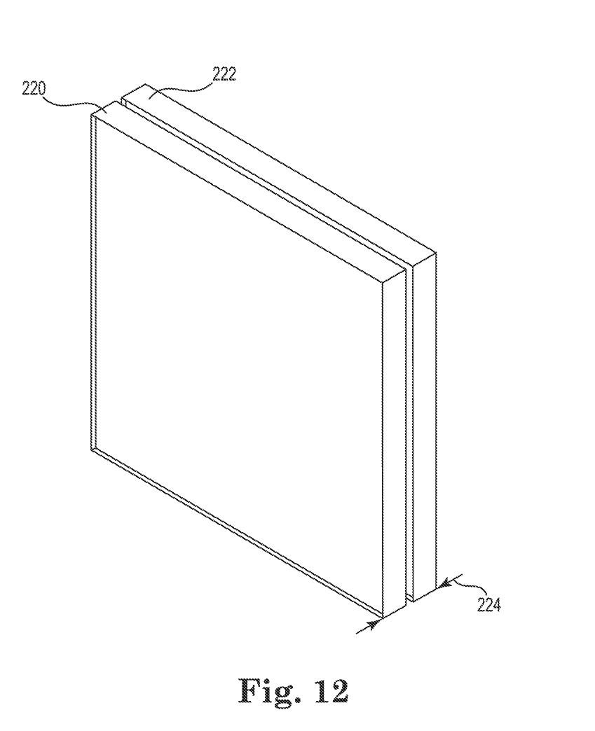

FIG. 1 is an exploded view of an edge-lit gridable light panel 50 with a reduced edge profile in accordance with an embodiment of the present disclosure. Frame members 52 are secured together by corner locks 54 to form frame structure 56 (see FIGS. 2A-2C) for the light panel 50. Optional frame cleats 58 and wall cleats 60 can be added to mount the light panel 50 to another surface. The frame members 52 are preferably extruded structures made from a variety of metals, plastics, ceramics, or combinations thereof. All of the features noted above are packaged within a frame depth 53 of less than about 1.5 inches, and preferably less than about 1.125″ for the single-sided frame. For a double-sided application (see FIG. 12) the frame depth 224 is less than about 2.0 inches, and preferably less than about 1.875″.

A stack 62 of panels 64A, 64B, 64C, 64D (“64”) are secured within the frame structure 56. The stack 62 includes back panel 64A behind light distribution panel 64B. The back panel 64A is preferably highly reflective, such as for example an aluminum panel with a polished white surface or reflective surface located behind the light distribution panel 64B.

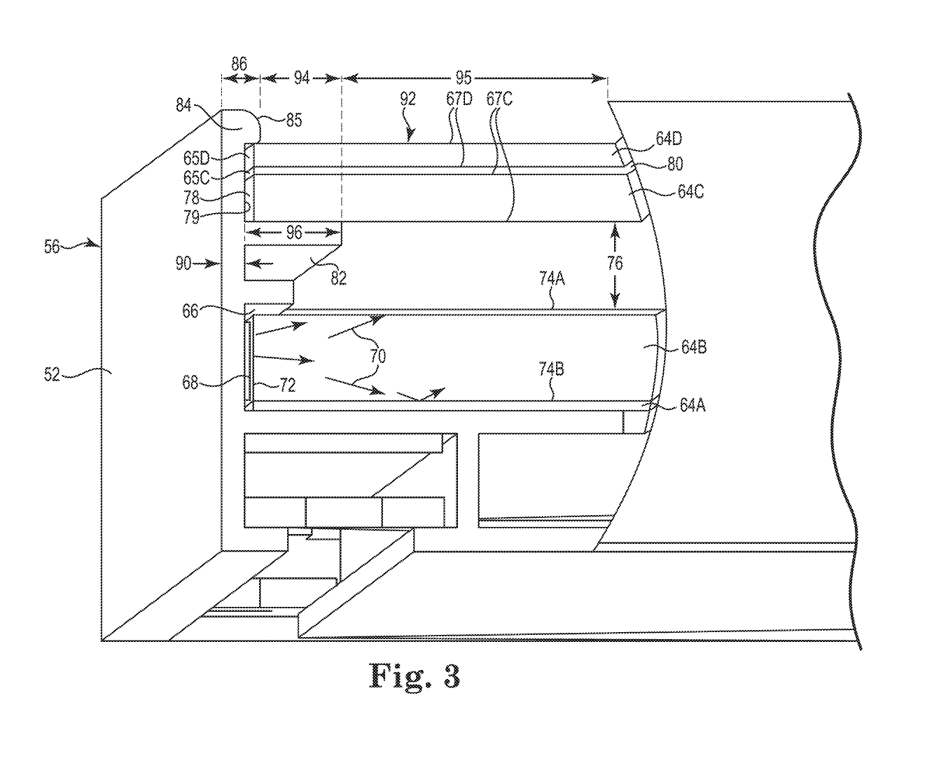

As best illustrated in FIG. 3, the panels 64A, 64B are held in intimate contact by the frame structure 56 within lighting recess 66. Light source 68, such as a strip of LED lights, is positioned within the lighting recess 66 to transmit light 70 into edge 72 of the light distribution panel 64B. In one embodiment the light source 68 is attached to the edge 72 of the light distribution panel 64B, such as by a mechanical fastener, adhesive bonding, or the like.

The light diffusion panel 64C and the optional lens 64D are retained in image recess 78 in the frame structure 56 in front of the light distribution panel 64B. The image recess 78 is sized to provide space for image 80 between the panels 64C and 64D. In the illustrated embodiment, gap 76 exists between the panels 64B and 64C. The image 80 may be an illuminated graphic, a non-illuminated graphic, or a three-dimensional image. Illuminated and non-illuminated graphics preferably share the same frame allowing both to be positioned adjacently with a minimal gap between images. The image 80 may be printed or displayed on a variety of substrates including films, plastics, papers, magnetized materials, and fabric. Three-dimensional images 80 may be constructed of a variety of materials that include metals, plastics, wood and composites thereof.

The image recess 78 includes front support 84 that retains the panels 64C, 64D in the frame structure 56 by extending onto the major surfaces 67C, 67D. Inside perimeter edge 85 of the front support 84 defines a viewable image area 92 that is less than the major surface 67D of the panel 64D (measured parallel to the surface 92). In an alternate embodiment, the light diffusion panel 64C is coupled directly with bottom surface 79 of the image recess 78, such as by an adhesive, two-sided tape, or a friction or interference fit.

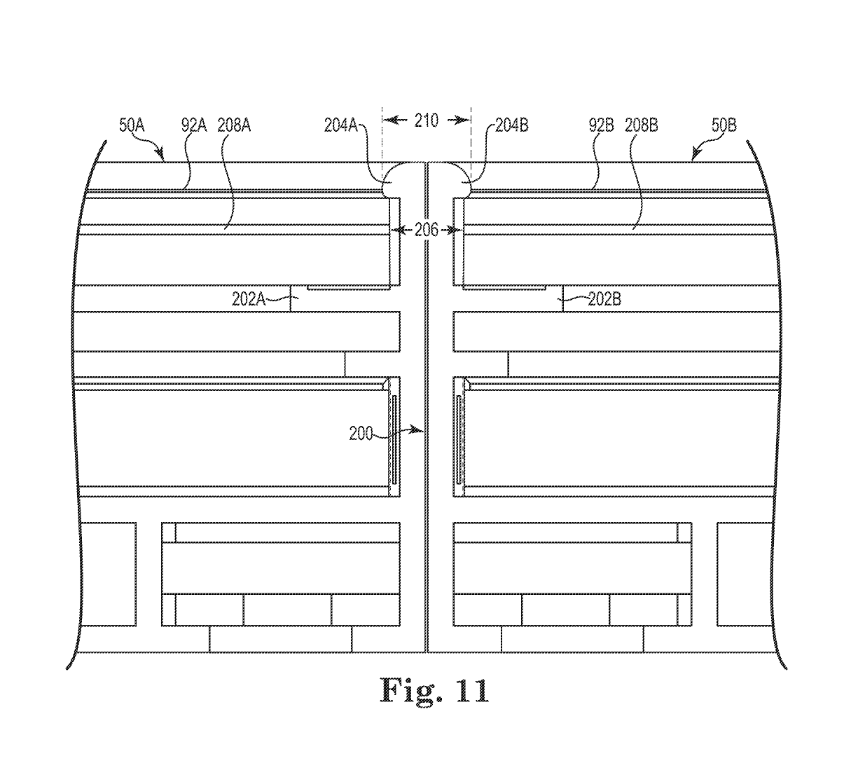

Width 86 of the front support 84 is preferably minimized to minimize the gap between adjacent images (see e.g., FIG. 11) and to reduce obstruction of the image 80. In the illustrated embodiment, the width is preferably less than about 0.150 inches, and more preferably less than about 0.100 inches. As a result, adjacent images can be located less than about 0.300 inches apart, and more preferably less than about 0.200 inches apart.

The front supports 84 also permit the image 80 to be substantially fully visible within the viewable image area 92. In one embodiment, the front supports 84 have a width 86 of about 0.100 inches. When nominal wall thickness 90 of the frame member 52 of about 0.060 inches is subtracted, the front support 84 preferably extends into perimeters 65C, 65D of the panels 64C, 64D by about 0.040 inches or less (measured parallel to the front surface 92). The front supports 84 preferably extend onto the viewable image area 92 less than about 0.100 inches, and preferably less than about 0.070 inches, and more preferably less than about 0.040 inches. As a result, at least 97%, and more preferably at least 98% of the image 80 is visible within the viewable image area 92 (depending upon the overall size of the image 80). For example, a standard light frame typically has a border of about one inch to hold a graphic in place that will obscure over 16% of a 22″×28″ image. The present fine line gridable light panel 50 allows 99.35% visibility of the same 22″×28″ image 80. In the preferred embodiment, less than about 3%, and preferably less than about 2% of a 24″×24″ the image 80 is obscured by the front supports 84.

The rear supports 82, on the other hand, have a width 96 that extends into the viewable image area 92 in overlapping region 94. This overlapping region 94 has the potential to create a shadow behind the image 80 in the viewable image area 92. (See FIG. 2A). The unobstructed portion 95 of the viewable image area 92 does not experience any shadowing due to the rear supports 82. In the illustrated embodiment, the rear support 82 has a width 96 of about 0.250 inches, and preferably less than 0.300 inches.

By minimizing the length of the rear support 82 required to optimally position the lens 64D, the diffuser 64C, and light distribution panel 64B within the frame 52, the resulting shadow is less visually impactful. This design results in a bright and even illumination over the entire image 80 to within a few millimeters of the edge of the graphic 80. The overlapping region 94 preferably has a width of less than about 0.300 inches, and more preferably about 0.250 inches.

In the preferred embodiment, the lens 64D is flexible polymeric sheet that can be removed from the frame structure 56 by bending, so that the image 80 can be serviced. In one embodiment, the lens 64D is a 0.060 inch thick sheet of PETG or PET-G (Polyethylene terephthalate glycol-modified available from Eastman Chemicals.

The light distribution panel 64B acts as a light guide and a light diffusing or light spreading structure. The light distribution panel 64B can be made from a variety of material, such as semitransparent or translucent polymethyl methacrylate (PMMA), sold under the tradenames Plexiglas, Acrylite, Lucite and Perspex. Other materials include polystyrene, polyurethane, polyvinylchloride, polyester, polycarbonate, polyimide, polyacrylic resin, acrylonitrile butadiene styrene (ABS), polypropylene, polyethylene, or a combination thereof.

A variety of light distribution panel 64B may be used in the present light panel 50. In one embodiment, the light diffusion panel 64A includes a filler that scatters and diffuses light. For example, a mineral filler particle like vitriolic barium having a mesh size of 300 and constituting an approximate 5% wt. of the thermoplastic can be added. Barium sulfate is a white pigment powder that can be used as filler in plastics and may act as a diffuser for a light source. The particle size is approximately 50 microns.

In another embodiment, a variety of structures can be formed on one or both major surfaces 74A, 74B (“74”) of the light diffusion panel 64A, such as disclosed in U.S. Pat. No. 8,534,902 (Wang, et al.); U.S. Pat. No. 8,215,818 (Morbieu et al.) and U.S. Pat. Publication Nos. 2010/0002437 (Pang et al.); 2011/0169429 (Ing et al.); and 2014/0007474 (Varveris), all of which are hereby incorporated by reference.

While the light source 68 is preferably light emitting diodes (LED), other light sources may be used, as including electroluminescent ceramics, electroluminescent wire, organic light emitting diode (OLED), neon, xenon and halogen lights. The light source 68 may be a single light source or a plurality of light sources. The LED's on the light source 68 may be arranged in any order or shape desired. The light source 68 preferably includes connectors for interconnecting several light sources to an electrical power source. The light source 68 may be flat, round or other shape and may be flexible or rigid.

The light source 68 may include a laminate structure with two or more layers. Suitable laminates for the light strip include films covering or partially covering the light strip having a surface relief pattern to enhance contrast or focus or disperse light. In another embodiment a binary phase grating may be used in the laminate structure for a larger viewing angle or a blazed phase grating for a narrower viewing angle.

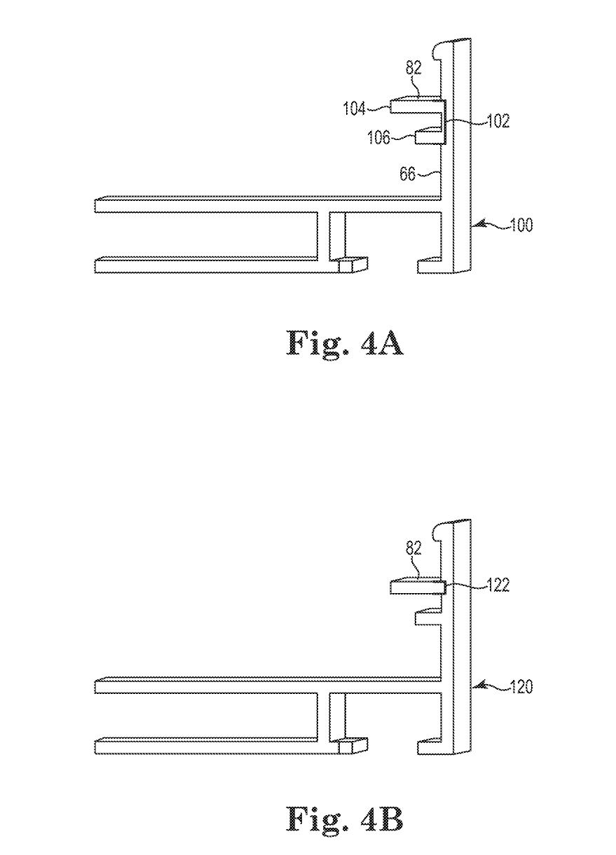

FIG. 4A is an end view of an alternate frame members 100 in accordance with an embodiment of the present disclosure. The extrusion 100 is formed with recess 102 sized to receive light transmitting insert 104. In the illustrated embodiment, the insert 104 includes both the rear support 82 and support 106 for the light recess 66. The insert 104 can be co-extruded with the frame member 100 or added as a discrete component, such as by adhesive bonding.

FIG. 4B is an end view of an alternate frame member 120 formed with recess 122 sized to receive a rear support 82 made from a light transmitting material. Again, the rear support 82 can be co-extruded with the frame member 120 or added as a discrete component.

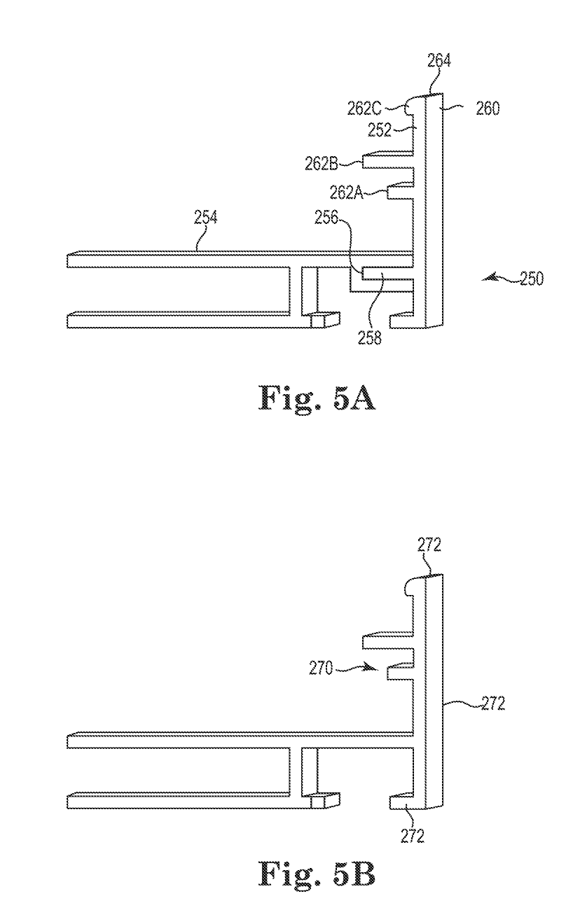

FIG. 5A is an end view of a two-part frame members 250 in accordance with an embodiment of the present disclosure. Side portion 252 is preferably extruded from a clear polymeric material, such as polycarbonate, while the rear portion 254 is preferably extruded from a light weight metal, such as aluminum. As a result, all of the structures 262A, 262B, 262C are transparent. Rear portion 254 includes recess 256 that receives protrusion 258 on the side portion 252. The rear portion 254 can be attached to the side portion 252 by a variety of techniques, such as adhesives, friction fit, and the like. External surface 260 of the side portion 252 preferably include a light impervious coating, such as chrome, that prevents light from escaping through the frame members 250. Leading edge 264 of the front support is also preferably coated.

FIG. 5B is an end view of an alternate frame member 270 extruded from a transparent polymeric material in accordance with an embodiment of the present disclosure. Selected surfaces 272 of the extrusion 270 are preferably coated with a light impervious coating to prevent light from escaping.

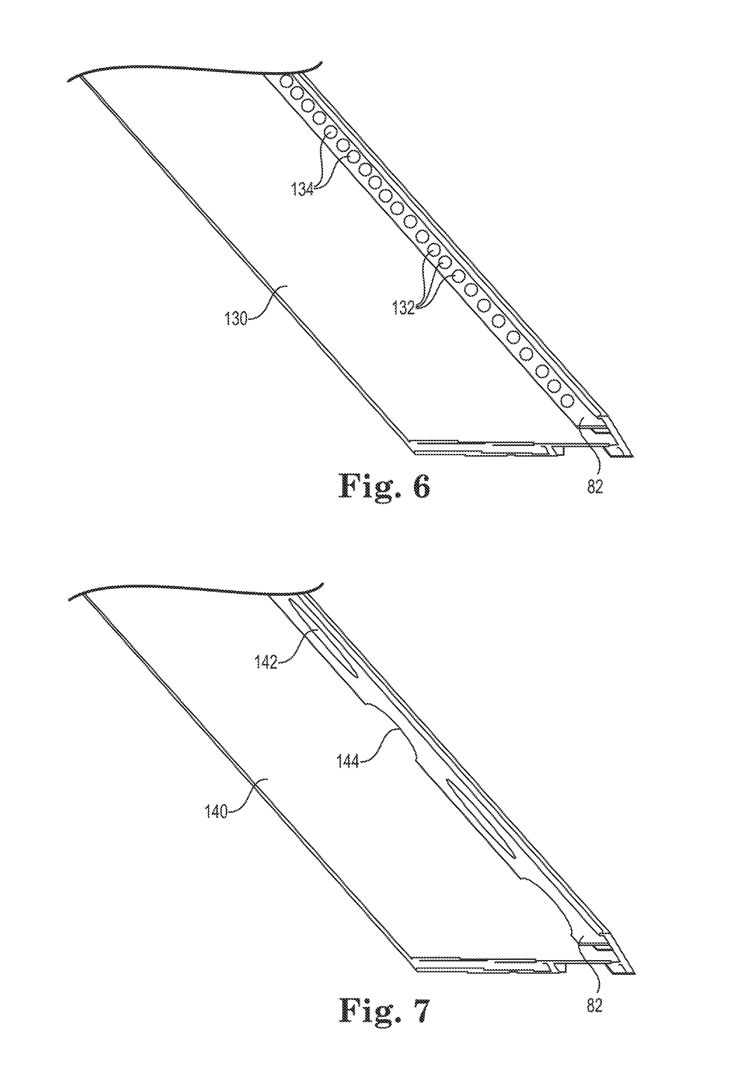

FIG. 6 is a perspective view of an alternate frame member 130 in which the rear support 82 is post-processed to include a plurality of light transmitting apertures 132. In one embodiment, divergent lenses 134 are optionally inserted into some or all of the apertures 132.

FIG. 7 is a perspective view of an alternate frame member 140 in which the rear support 82 is post-processed to include both apertures 142 and edge recesses 144 to facilitate light transmission to the viewable image area 92.

Using the embodiments disclosed herein, light transmitted to the viewable image area in the overlapping region exhibits an intensity at least 25% greater than a light intensity exhibited in an overlapping region of a rear support without any of the light transmitting structures discussed above.

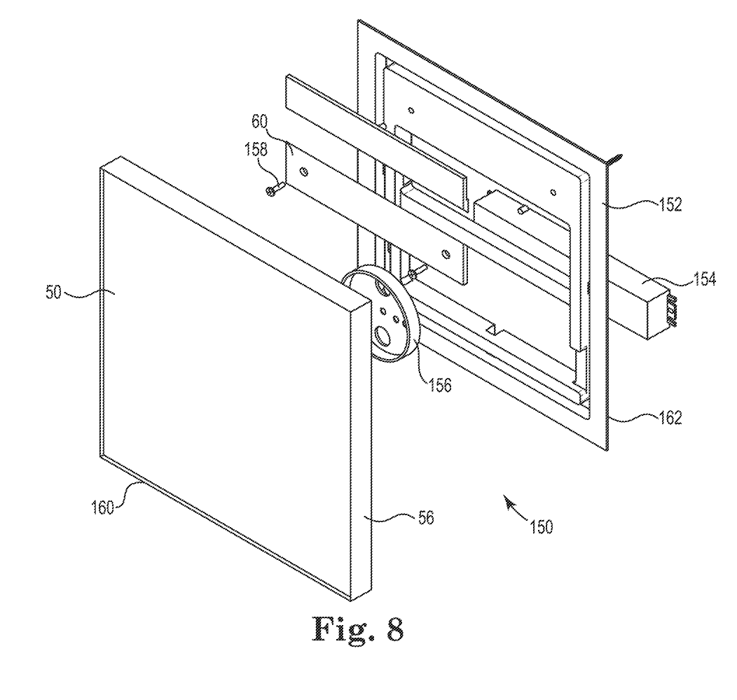

FIG. 8 is a perspective view of a light panel assembly 150 including a light panel 50 and backer panel 152 in accordance with an embodiment of the present disclosure. The backer panel 152 includes power supply 154 and junction box 156 that electrically couples with the light panel 50. The power supply 154 includes an AC/DC power adapter that converts AC power to DC power and supply such DC power to the light source 68.

Wall cleat 60 is attached to the backer panel 152 using fasteners 158. Fame cleat 58 is attached to the rear of the light panel 50 in a location so that the outer perimeter 160 of the frame structure 56 is generally aligned with outer perimeter 162 of the backer panel 152. The backer panel 152 can be attached to any other structure using a variety of well-known techniques.

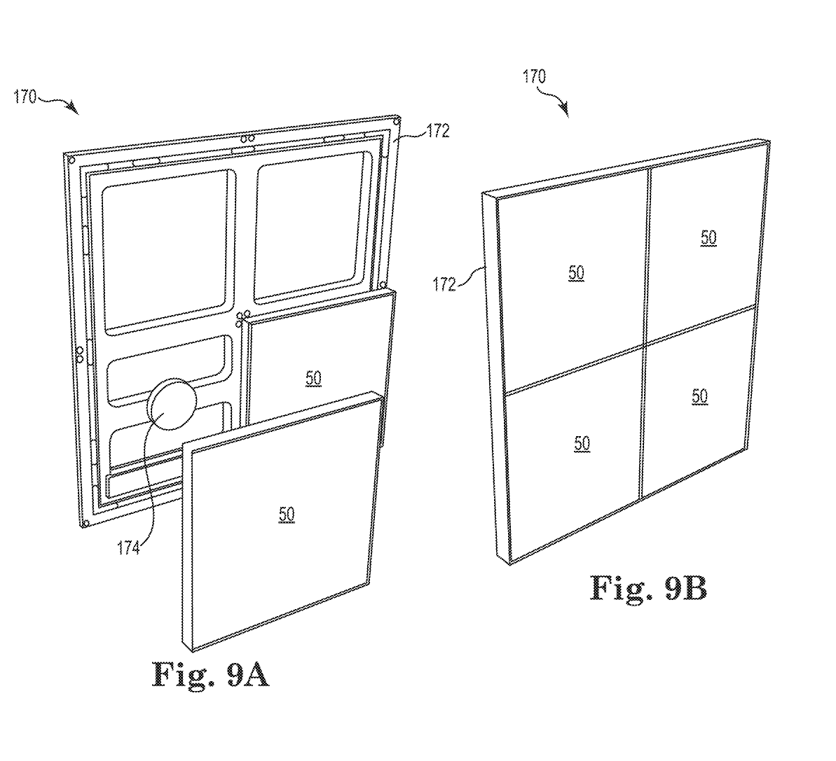

FIGS. 9A and 9B illustrate an array assembly 170 for a plurality of light panels 50 in accordance with an embodiment of the present disclosure. Backer panel 172 is sized to receive a plurality of light panels 50 and includes one or more junction boxes 174 for providing electrical power to each of the panels 50. The light panels 50 can be attached to the backer panel 172 using the frame cleat and wall cleat discussed above, magnets, or a variety of other mechanical structures.

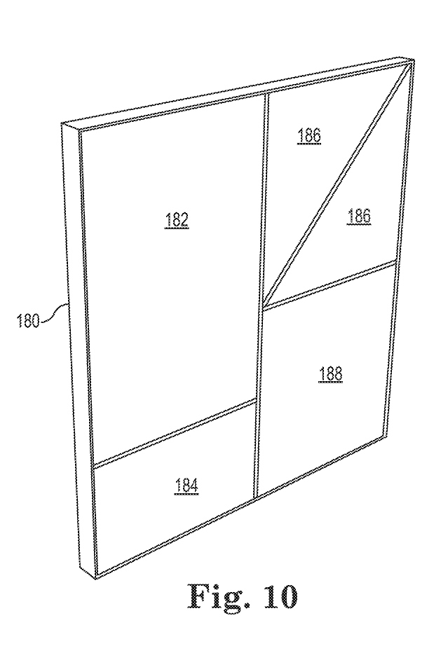

FIG. 10 illustrates an alternate array assembly 180 with light panels 182, 184, 186, 188 of differing sizes and shapes, including non-rectangular shapes.

FIG. 11 is a sectional view illustrating an interface 200 of two light panels 50A, 50B (“50”) in accordance with an embodiment of the present disclosure. Rear supports 202A, 202B (“202”) are preferably one of the light transmitting structures disclosed herein. Front supports 204A, 204B (“204”) are abutted in a back-to-back arrangement to minimize edge-to-edge gap 206 between adjacent images 208A, 208B (“208”). In the illustrated embodiment, the adjacent viewable image areas 92A, 92B (“92”) are separated by a gap 210 of less than about 0.300 inches, and preferably less than about 0.250 inches.

FIG. 12 is a perspective view of a pair of light panels 220, 222 arranged in a back-to-back configuration in accordance with an embodiment of the present disclosure. The light panels 220, 222 preferably have an overall thickness 224 of less than about 2.0 inches, and preferably less than about 1.875 inches.

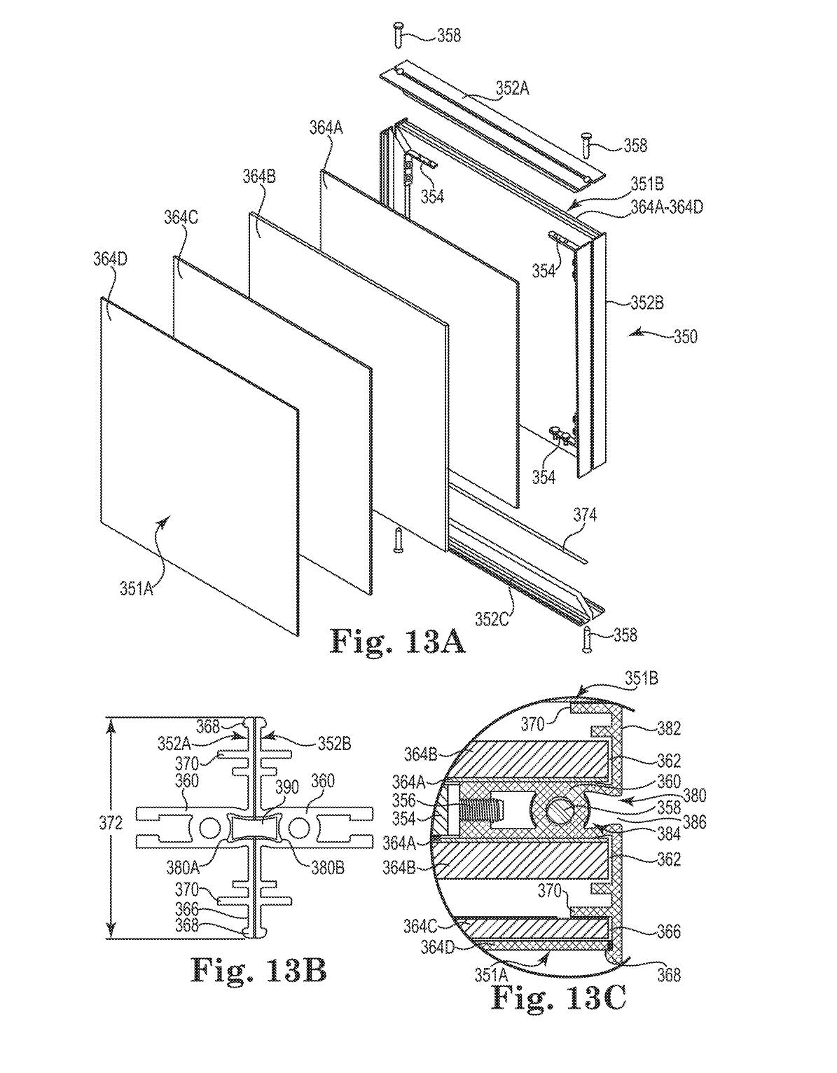

FIGS. 13A-13C illustrates an alternate two-sided light box 350 with unitary frame members 352A-352D in accordance with an embodiment of the present disclosure. Corner clips 354 are attached along inside perimeter to opposing frame member 352A, 352C using fasteners 356. Fasteners 358 engage with the corner clips 354 to attach opposing frame members 352B, 352D, to complete the two-sided light box 350. The frame members 352 are preferably extruded structures made from a variety of metals, plastics, ceramics, or combinations thereof.

The frame members 352 include center structures 360 that engage with the corner clips 354 and the fasteners 356, 358. On each side of the center structure 360 are stacks 351A, 351B of panels 364A-364D held by the frame members 352, as discussed in connection with FIG. 3. Light recesses 362 containing LED lights 374 (see FIG. 13A), highly reflective panels 364A, and light distribution panels 364B and light diffusion panels 364C and lens 364D are retained in image recesses 366 in the frame structure 352 between front supports 368 and rear supports 370.

In the illustrated embodiment, opposite sides of the center structure 360 are preferably symmetrical so a single frame member 352 can support the same light box structure on each side. In an alternate embodiment, the frame members are asymmetrical so different variations of the light boxes are positioned on each side. The resulting two-side light box 350 preferably has a compact shape with an overall thickness 372 less than about 2.0 inches.

The present two-sided light box 350 is also gridable, such as illustrated in FIGS. 9 and 10. The center structure 360 of the frame member 352 includes recess 380 positioned along outside surface 382. The recess 380 preferably includes a base 384 that is wider than the opening 386.

As best illustrated in FIG. 13B, coupling structure 390 can be slid longitudinally into adjacent recesses 380A, 380B of adjacent frame members 352A, 352B to interconnect adjacent light boxes 350 (see e.g., FIG. 10). The coupling structure 390 preferably has a cross-sectional profile that corresponds to the shape of the adjacent recesses 380A, 380B. The coupling structure 390 can be constructed from a variety of materials, such as metal, plastic, and the like.

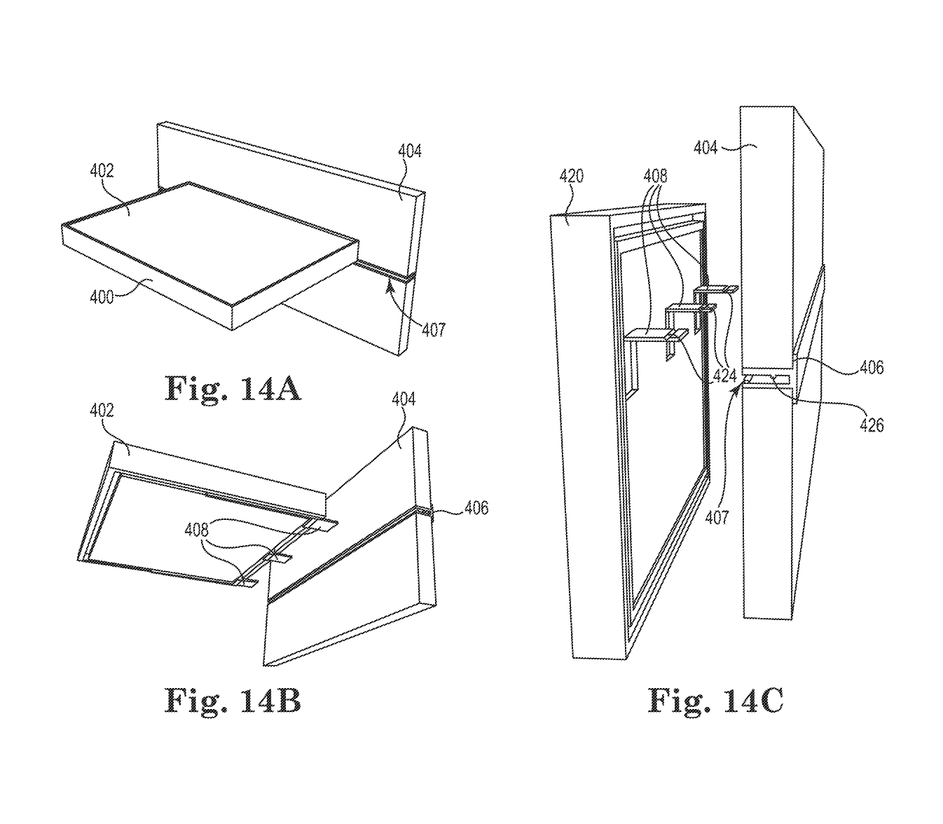

FIGS. 14A and 14B illustrate and embodiment of the present light panel 400 configured for use as a lighted shelf 402. In the illustrated embodiment, support structure 404 includes a hollow support track 406 with an opening 407 configured to mate with corresponding support brackets 408 on the lighted shelf 402. For example, the support track 406 can be configured with an internal low-voltage electrode. An electrical contact on the support brackets 408 electrically couples with the electrode when the lighted shelf 402 is mounted to the support structure 404.

FIG. 14C illustrates a vertical application of the support structure 404 with the powered support track 406. The illustrated light panel 420 includes the support brackets 408 extending perpendicular from rear surface 422 to facilitate vertical mounting. Electrical contacts 424 on the support brackets 408 electrically couple with electrodes 426 on the support track 406 when the light panel 420 is mounted.

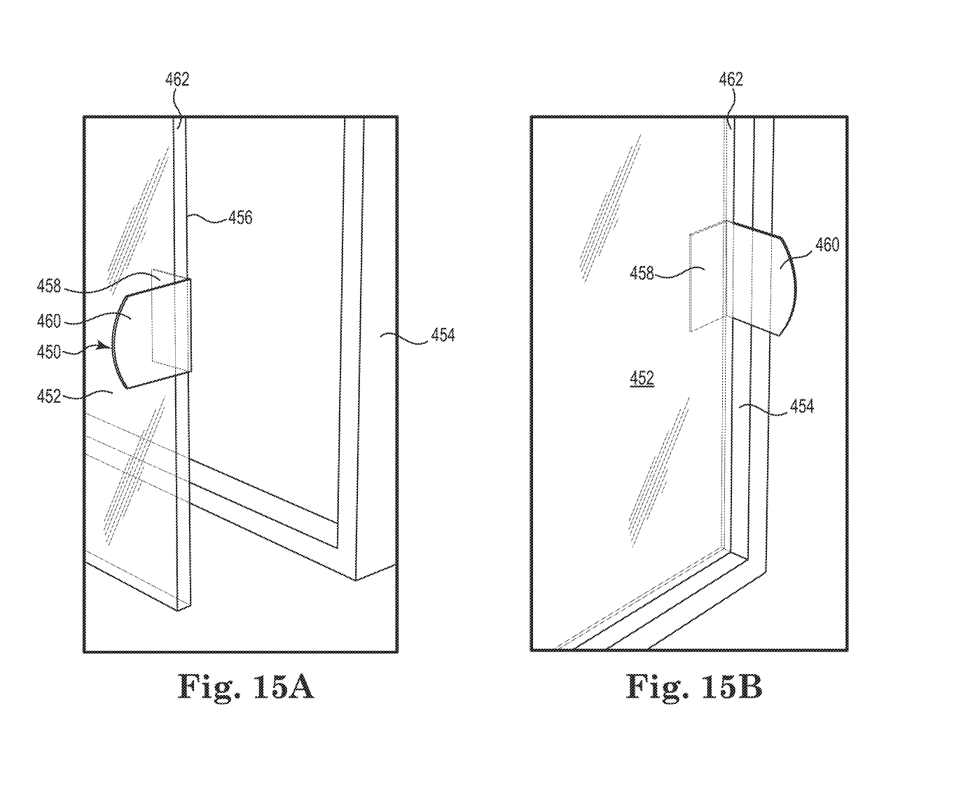

FIGS. 15A and 15B illustrate transparent removal tabs 450 attached to the lens 452 to facilitate insertion and removal from the fine line frame 454 in accordance with an embodiment of the present disclosure. Removal tabs 450 are attached to rear surface 456 of the lens 452 with a transparent adhesive 458. As best illustrated in FIG. 15B, distal portions 460 of the removal tabs 450 fold around edges 462 of the lens 452 and extend beyond the fine line frame 454. The transparent removal tabs 450 and transparent adhesive 458 are substantially invisible.

The distal portions 460 can be used to both insert the lens 452 into the fine line frame 454 and for removal of the lens 452. The unique design of the lens 452 (discussed above), combined with the transparent removal tabs 450, allows the graphic images to be easily inserted and/or replaced without tools or removing the frame from its display position.

Where a range of values is provided, it is understood that each intervening value, to the tenth of the unit of the lower limit unless the context clearly dictates otherwise, between the upper and lower limit of that range and any other stated or intervening value in that stated range is encompassed within this disclosure. The upper and lower limits of these smaller ranges which may independently be included in the smaller ranges is also encompassed within the disclosure, subject to any specifically excluded limit in the stated range. Where the stated range includes one or both of the limits, ranges excluding either both of those included limits are also included in the disclosure.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the various methods and materials are now described. All patents and publications mentioned herein, including those cited in the Background of the application, are hereby incorporated by reference to disclose and described the methods and/or materials in connection with which the publications are cited.

The publications discussed herein are provided solely for their disclosure prior to the filing date of the present application. Nothing herein is to be construed as an admission that the present disclosure is not entitled to antedate such publication by virtue of prior invention. Further, the dates of publication provided may be different from the actual publication dates which may need to be independently confirmed.

Other embodiments are possible. Although the description above contains much specificity, these should not be construed as limiting the scope of the disclosure, but as merely providing illustrations of some of the presently preferred embodiments. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form varying modes disclosed. Thus, it is intended that the scope of at least some of the present disclosure should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

What is claimed is:

1. A gridable light panel comprising:
a light diffuser panel;
a frame structure having an inner surface capturing edges of the light diffuser panel, the inner surface of the frame structure comprising;
front supports comprising an inner edge surrounding a viewable image area less than a front surface of the light diffuser panel, the front supports comprising a width of less than about 0.100 inches measured parallel to the viewable image area;
rear supports supporting a rear surface of the light diffuser panel, the rear supports extending into the viewable image area in an overlapping region;
a light distribution panel located in the frame structure behind the rear supports relative to the light diffuser panel;
a light source located within the frame structure and optically coupled to at least one edge of the light distribution panel; and
an image secured to the front surface of the light diffuser panel by the front supports, wherein at least 97% of the image is visible in the viewable image area.

2. The gridable light panel of claim 1 wherein the front supports extend on the front surface of the light diffuser panel by less than about 0.070 inches.

3. The gridable light panel of claim 1 wherein the front supports extend on the front surface of the light diffuser panel by about 0.040 inches.

4. The gridable light panel of claim 1 comprising a lens secured over the image by the front supports.

5. The gridable light panel of claim 4 comprising transparent removal tabs affixed to the lens, the transparent removal tabs comprising a transparent film attached to a rear surface of the lens by a transparent adhesive, the transparent removal tabs comprising distal portions extending above the frame structure.

6. The gridable light panel of claim 1 wherein the overlapping region comprises a width of less than about 0.300 inches.

7. The gridable light panel of claim 1 wherein the overlapping region comprises a width of about 0.250 inches.

8. The gridable light panel of claim 1 wherein the rear support comprises a transparent material.

9. The gridable light panel of claim 1 wherein the rear support comprises a light transmitting insert secured to inner surface of the frame structure.

10. The gridable light panel of claim 1 comprising light transmitting structures in the rear supports transmitting light to the viewable image area in the overlapping region with an intensity at least 25% greater than a light intensity exhibited in an overlapping region of a rear support without light transmitting structures.

11. The gridable light panel of claim 10 wherein the light transmitting structures comprise one or more apertures in the rear support.

12. The gridable light panel of claim 1 wherein the frame structure comprises
a transparent material; and
a coating selectively applied to selectively block the transmission of light.

13. The gridable light panel of claim 1 comprising:
a backer panel configured to support the gridable light panel; and
a power supply for the light source mounted to the backer panel.

14. The gridable light panel of claim 1 comprising:
at least one support bracket attached to the gridable light panel, the support bracket comprising at least one electrical contact electrically coupled to the light source; and
a support track with a recess receiving the at least one support bracket, the support track comprising at least one electrical contact electrically couple with the electrical contact on the support bracket so a power source connected to the electrical contact on the support track powers the light source.

15. The gridable light panel of claim 1 comprising a support structure that supports the gridable light panel horizontally.

16. A plurality of the gridable light panels of claim 1 mounted horizontally as a plurality of shelves.

17. A plurality of the gridable light panels of claim 1 arranged in an array so adjacent viewable image areas are separated by a gap of less than about 0.300 inches, wherein adjacent images can be any combination of illuminated images and non-illuminated images.

18. A plurality of the gridable light panels of claim 1 arranged in an array so adjacent viewable image areas are separated by a gap of less than about 0.200 inches.

19. A gridable light panel comprising:
a light diffuser panel;
a frame structure having an inner surface capturing edges of the light diffuser panel, the inner surface of the frame structure comprising;
front supports comprising an inner edge surrounding a viewable image area less than a front surface of the light diffuser panel;
rear supports supporting a rear surface of the light diffuser panel, the rear supports extending into the viewable image area in an overlapping region;
a light source located within the frame structure and optically coupled to at least one edge of the light diffuser panel;
an image secured to the front surface of the light diffuser panel by the front supports;
a lens secured over the image by the front supports; and
transparent removal tabs affixed to the lens facilitating removal of the lens from the frame structure.

20. The gridable light panel of claim 19 wherein the transparent removal tabs comprise a transparent film attached to a rear surface of the lens by a transparent adhesive, the transparent removal tabs comprising distal portions extending above the frame structure.
